(19) United States
(12) Patent Application Publication
(10) Pub. No.: US 2005/0122682 A1
(43) Pub. Date: Jun. 9, 2005

(54) Electronics arrangement

(76) Inventors: Robert Streit, Oberwangen b. Bern (CH); Hendrik Koopmans, Urtenen (CH)

Correspondence Address: MATTHEW R. JENKINS, ESQ., 2310 FAR HILLS BUILDING, DAYTON, OH, 45419, US

(21) Appl. No.: 10/432,893

(22) PCT Filed: Nov. 19, 2001
(86) PCT No.: PCT/CH01/00678

(30) Foreign Application Priority Data
Dec. 8, 2000 (CH) 2397/00

(51) Int. Cl. H05K 7/20

(52) U.S. Cl. 361/695; 361/697; 165/80.3; 415/178

(57) ABSTRACT

An electronics arrangement has at least one ventilator and at least one essentially flat support structure which is fitted with one or more electronic components and which is provided with one or more cooling ribs. A cooling air passage passing through the flat support structure is configured therein. The ventilator and the cooling air passage are configured and arranged in such a way that the ventilator produces a cooling air stream, so that the cooling air first passes along one side of the support structure, in a function whereby at least one component and/or a cooling rib are cooled, then passes through the cooling air passage and subsequently, flows along the other side of the support structure in a function whereby at least one electronic component and/or a cooling rib are cooled. This enables efficient cooling of the electronic components of the electronic arrangements.

### TECHNICAL FIELD

The invention relates to an electronics arrangement as claimed in the precharacterizing clause of claim 1.

### PRIOR ART

Electronics arrangements normally comprise one or more flat mount structures, in the form of panels, such as printed circuit boards, on which the electronic components are arranged. Two or more such mount structures in the form of panels, or mounting boards, are often arranged parallel to one another in a framework, which is also referred to as a rack, and/or in a housing.

In order to dissipate the heat losses which are produced by the electronic components, electronics arrangements are frequently also provided with a large number of cooling ribs, which are connected with a heat-conducting function to the electronic components and/or to the mounting board. The heat losses are then dissipated from the electronic components by means of thermal conduction to the cooling ribs, and from these by means of convection to the cooling air. If the mounting boards are equipped with integrated components and/or electronic power components which produce large heat losses, heat dissipation by means of thermal conduction is often not sufficient on its own to protect the components effectively against thermally produced damage. One solution approach in this case is to also provide the electronics arrangements with a fan, which produces a forced cooling air flow in order to dissipate the heat losses by convection.

In order to ensure good thermal conduction, the cooling ribs are in close contact with the mounting board and/or with the electronic components. Although the cooling ribs, in principle, may also be fit directly to a printed circuit board and/or to the electronic components, they are generally integrally formed on a normally integral heat sink, which is itself firmly connected to the printed circuit board or mounting board, with a heat conducting function. The components which produce heat can be connected directly to the heat sink, either with a cooling part, which is typically fit to such components, being connected by means of a relatively thick bolt through the printed circuit board to the heat sink, or with a cooling part such as this being mounted directly on the heat sink, through a cutout in the printed circuit board.

In this case, a heat sink such as this is typically provided with a base plate (also referred to as a cold plate), on which the cooling ribs are integrally formed, with the cold plate preferably being in the form of a panel corresponding to the printed circuit board that is to be cooled. The assembly which is formed from a printed circuit board and from a cold plate which corresponds to it is thus itself once again a structure in the form of a panel and is used as a mount structure to which the electronic components and cooling ribs are fit. In this case, either a printed circuit board and a heat sink which is provided with a cold plate are formed as separate elements and are firmly connected to one another, or the cold plate may from the start be in the form of an integral part of the printed circuit board, in order to form the mount structure, which is in the form of a panel, for the electronics arrangement. The structure provided with cooling ribs and electronic components can also be provided with covering panels or with covering or housing elements with a similar effect, which form a casing which guides the cooling air flow along predetermined flow paths. In particular, the cooling ribs may be covered by covering elements which are arranged essentially parallel to the mounting board, so that they define cooling air channels that are closed on four sides, in the form of cooling tubes.

JP 10-233590 describes an electronics arrangement with a printed circuit board on which a flat electronic component that produces heat losses is arranged. The two main faces of the flat electronic component lie on the printed circuit board, while a heat sink which is provided with cooling ribs is fit on the other main face. The electronics arrangement also has a fan, which produces a cooling air flow such that the cooling air flows along the cooling ribs of the heat sink, and in the process cools them. According to one variant, which is illustrated in FIG. 4 of JP 10-233590, the fan is arranged directly on the printed circuit board, immediately adjacent to the heat sink, such that its axis is at right angles to the plane of the printed circuit board. The fan sucks in the cooling air in the axial direction from the side facing away from the printed circuit board, and blows it out in the radial direction (that is to say parallel to the plane of the printed circuit board), such that it flows along the cooling ribs through the heat sink that is provided with a casing.

The cooling efficiency of a cooling apparatus such as that which is described in JP 10-233590 is rather low. Furthermore, the cooling apparatus itself occupies a comparatively large amount of space in comparison to the electronic components to be cooled, which is undesirable, especially in the case of electronics arrangements which can be inserted as flat units into a rack. The installation height or the thickness of such push-in units should be as small as possible in order to allow them to be arranged in a compact rack or in a compact appliance housing

### DESCRIPTION OF THE INVENTION

The object of the invention is to provide an electronics arrangement having a cooling apparatus, which is space-saving and allows efficient cooling of electronic components of the electronics arrangement.

The object is achieved as defined by the features of claim 1. According to the invention, an electronics arrangement has at least one fan and at least one essentially flat mount structure, which is equipped with one or more electronic components and is provided with one or more cooling ribs. A cooling air passage is formed in the mount structure, and passes through it. The fan and the cooling air passage are designed and arranged such that the fan produces a cooling air flow such that the cooling air first of all flows along one face of the mount structure in a function whereby at least one electronic component and/or a cooling rib are cooled, then flows through the cooling air passage, after which it flows along the other face of the mount structure in a function whereby at least one electronic component and/or a cooling rib are cooled.

For the purposes of the present description and the claims, a flat structure is a structure which has two essentially mutually parallel flat faces, which are referred to as the main faces of the structure and have considerably larger surface areas than the other edge faces and/or end faces of the structure. A passage passing through a flat structure in this case means a passage which passes through the two main faces of the structure essentially at right angles to the surfaces of the main faces.

The cooling air first of all flows along the surface of one of the two main faces of the flat mount structure, which is in the form of a panel, and in the process cools components and/or cooling ribs which are arranged on this main face of the mount structure. After this, the cooling air flows through the cooling air passage that is formed in the mount structure and passes through the flat structure, which is in the form of a panel, transversely with respect to the plane of the panel. It then flows along the surface on the other main face of the mount structure, and in the process cools the components and/or cooling ribs which are arranged on this main face of the mount structure.

The cooling air passage which is formed in the mount structure allows the fan to produce a cooling air flow on both faces of the mount structure. This makes it possible not only to cool the electronic components directly but also to dissipate the heat which is passed from these components to heat sinks and is radiated from them in an efficient manner by means of the same cooling air flow that is produced by the fan. Furthermore, the thickness of the mount structure and its installation height are not increased by the passage.

All the electronic components can be arranged on the first main face of the mount structure, and all the cooling ribs can be arranged on its second main face. However, alternatively, some or even all of the electronic components may be arranged on the second main face, or some or even all of the cooling ribs may be arranged on the first main face.

According to one preferred embodiment of the invention, the fan is fit either directly to the flat mount structure itself or to a holding apparatus which is connected to the mount structure. A holding apparatus such as this may, for example, be a covering panel, which is designed to cover one of the two main faces of the mount structure, and is fit to it. The mount structure together with the covering panel or panels, the fan and, if appropriate, the fan holding apparatus may, in particular, be in the form of a unit which can be pushed into a rack as an entity. In principle, however, it is also possible to arrange the fan at a point that is at a distance from the mount structure, for example at a suitable point in an appliance housing.

The fan is preferably of such a size and is arranged on the mount structure such that it does not project above the highest component and/or the highest cooling ribs in the direction at right angles to the surfaces of the main faces of the flat mount structure in order not to increase the thickness of the mount structure or its installation height.

In the case of a fan which is fit to the mount structure or to a holding apparatus that is connected to the mount structure, this fan is preferably arranged radially immediately adjacent to the cooling air passage or even in the cooling air passage itself. In this case, a radial arrangement of the fan with respect to the mount structure means an arrangement of the fan such that the fan axis (that is to say the axis of the impeller of the fan) is arranged essentially at right angles to the main faces of the flat mount structure. An arrangement of the fan immediately adjacent to the cooling air passage means that the fan is arranged in the immediate vicinity of the cooling air passage that is formed in the mount structure. It may, for example, be arranged with an axial inlet opening to the cooling air passage resting flush on one main face of the mount structure in which the cooling air passage is formed.

The radial arrangement of the fan in the immediate vicinity of the cooling air passage formed in the mount structure, or even in this mount structure itself, makes it possible to use a fan with an impeller which has a comparatively large diameter without this increasing the installation height or the thickness of a push-in unit which comprises the mount structure together with the fan. Fans with large impellers are more efficient and can be operated at lower rotation speeds than fans with small impellers. This allows the noise level to be reduced, the probability of failures to be decreased, and the life expectancy of the fans to be increased.

The fan may be provided at one axial longitudinal end with a cover (for example in the form of a covering panel) which is arranged transversely with respect to the fan axis and prevents air from being sucked in (if it is arranged at the longitudinal end on the inlet side) or from being blown out (if it is arranged at the longitudinal end on the outlet side) in the axial direction. A cover such as this may be a covering panel which is designed to cover one of the two main faces of the mount structure and is fit to it. However, a cover in the form of a covering panel is also feasible which covers only the fan inlet or the fan outlet in the axial direction, without at the same time also covering the entire main face of the mount structure. Furthermore, the cover may also at the same time be in the form of a holding apparatus for holding the fan. The mount structure is preferably provided on the outlet side with a covering panel which is preferably at the same time also used as a cooling channel cover.

The fan may also be provided at its two axial longitudinal ends with in each case one cover that is arranged transversely with respect to the fan axis. It then sucks in air on its inlet side in the vicinity of one longitudinal end only in the radial direction, and blows air out on its outlet side in the vicinity of the other longitudinal end only in the radial direction.

According to one preferred variant of the invention, the mount structure comprises a printed circuit board, which is equipped with electronic components on merely one side, and a cold plate which is provided with cooling ribs on merely one side, with this cold plate, which is also referred to as a heat sink (in the form of a panel) being connected by its face on which there are no cooling ribs to the face of the printed circuit board on which there are no electronic components. Overall, the mount structure is then a flat structure in the form of a panel with two main faces, with one main face being equipped with electronic components and the other main face being provided with cooling ribs. The entire mount structure is preferably in the form of a push-in unit, which can be pushed into a rack as an entity. In principle, however, other shapes of the mount structure overall and, in particular, of the printed circuit board and/or of the heat sink are also possible.

The electronic components, the cooling ribs and the fan of an electronics arrangement according to the invention are preferably arranged such that the cooling air flow which is produced by the fan initially cools at least one electronic component on one face of the mount structure, then flows through the cooling air passage, after which it cools at least one cooling rib on the other face of the mount structure. This makes it possible in particular to efficiently cool even those electronic components which are not connected with any heat conducting function to any cooling ribs.

At least some of the cooling ribs of an electronics arrangement according to the invention are advantageously designed and arranged in the form of flow guidance walls which, on at least one face (that is to say on a main face) of the mount structure, define channel walls for the cooling air flow. The ribs then have two functions at the same time: firstly, they are used as cooling ribs via which heat is dissipated to the cooling air, and secondly they are used as guidance walls or channel walls for guiding the cooling air flow.

In this case, a covering panel which is essentially parallel to the flat mount structure or a covering element with the same function as a covering panel can be arranged on that face of the cooling ribs which define the cooling air channels which faces away from the mount structure, such that at least one of the cooling air channels, and preferably even all of the cooling air channels, is or are bounded on two sides by cooling ribs, on a third side by the mount structure, and on a fourth side which is opposite this third side, by the covering panel or covering element. The cooling air channels which are closed on four sides such as these make it possible to provide a precisely defined flow path for the cooling air flow.

According to a further preferred embodiment of the invention, at least one further cooling air passage is formed in the mount structure and flow guidance means are arranged such that, after flowing along the first face of the mount structure and flowing through the first cooling passage which leads from the first face to the second face of the mount structure, at least some of the cooling air is passed to the further cooling air passage by the flow guidance means on the second face, and flows through this cooling air passage back to the first face of the mount structure in order then once again to flow along the first face of the mount structure, in the process cooling at least one electronic component and/or one cooling rib. The flow guidance means may, for example, be guidance walls or guidance channels which guide or carry the flow, with these guidance walls or guidance channels preferably at the same time also being in the form of cooling ribs for cooling electronic components of the electronics arrangement. The further cooling air passage makes it possible to cool electronic components and/or cooling ribs even in those parts on the first face of the mount structure over which the cooling air flow does not pass before it passes through the first cooling air passage. One or more separating walls are preferably provided on the first face of the mount structure, which bound the areas around the first cooling air passage from the areas around the further cooling air passage or passages, in order to prevent the cooling air from flowing back to the first passage on the first face of the mount structure after flowing through the further passage or passages, and thus from being recycled in an undesirable manner. These separating walls may either be arranged on the mount structure itself, on its first face, or they may also be arranged on a covering panel, which is arranged parallel to this first face, in order to prevent air flows at right angles to the planes of the panel.

However, it is also possible for the mount structure to have only a single cooling air passage, so that the entire cooling air flow is sucked in along one main face of the mount structure, and is blown out along the other main face.

Except for the first and, if appropriate, the other passages for the cooling air flow, the flat mount structure advantageously has no other passage through which air can pass and which passes through the mount structure, in order to ensure a precisely defined flow path for the cooling air.

The fan, the cooling air passage or passages and, if appropriate, the flow guidance means may be arranged such that the cooling air is first of all sucked in through an air inlet which is arranged in the vicinity of a first end face of the mount structure, and such that, after it has flowed along the mount structure and has hence cooled the electronic components and/or cooling ribs, the cooling air is blown out through an air outlet which is arranged in the vicinity of another end face of the mount structure, which is not the same as the first end face. The air outlet may, for example, be arranged in the vicinity of that end face which is arranged opposite the first end face with respect to the mount structure. In this case, the cooling air may in each case flow essentially over the entire mount structure, in sections, on one or the other of the main faces. The first end face may, for example, be arranged at the front, with the second end face being arranged at the rear, of a rack or of an appliance housing in which the mount structure or the mount structure which has been assembled with covering panels or other covering elements to form a push-in unit is installed. After installation, the cooling air is then sucked into the front and is blown out of the rear, in the normal way. The first end face on the air inlet side and the second end face on the air outlet side may, however, be arranged on other faces of the rack or of the appliance housing, for example on its bottom face or top face, thus producing a cooling air flow which runs essentially upwards from the bottom. It is also possible to suck in the air at the front and to blow it out at the top, thus producing a flow from the front upwards, in which case the flow does not need to be in a straight line. Further advantageous embodiments and feature combinations of the invention can be found in the following detailed description and from the totality of the patent claims.

### BRIEF DESCRIPTION OF THE DRAWINGS

In the drawings which are used to explain the exemplary embodiment:

FIG. 1 shows a simplified, perspective view of one face of an electronics arrangement according to one preferred embodiment of the invention;

FIG. 2 shows a simplified, perspective view of a second face of the electronics arrangement shown in FIG. 1.

In principle, identical parts are provided with the same reference symbols in the figures.

### APPROACHES TO IMPLEMENTATION OF THE INVENTION

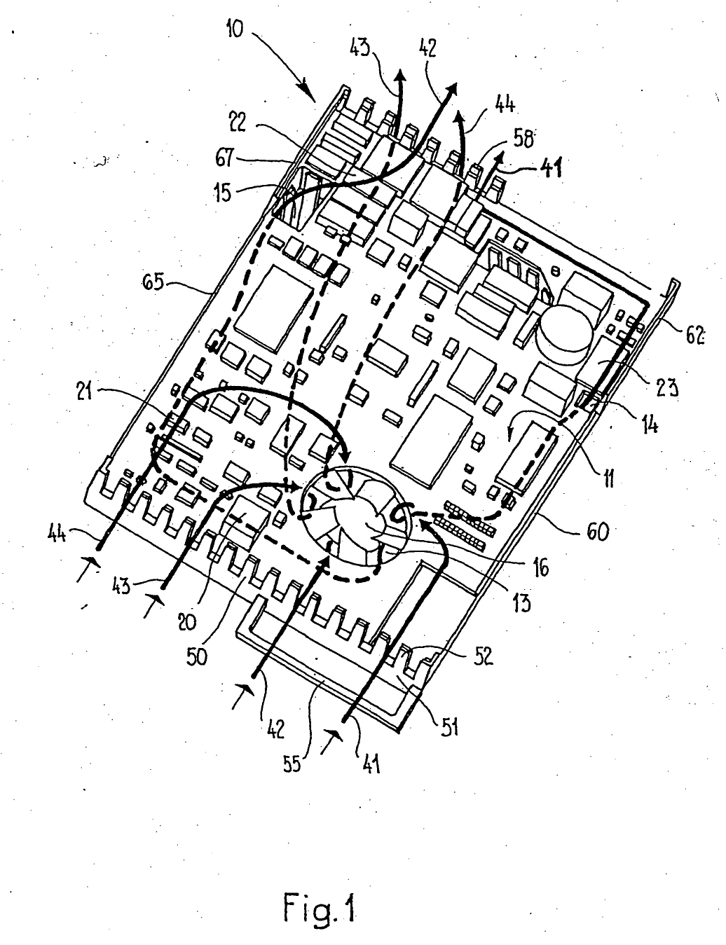

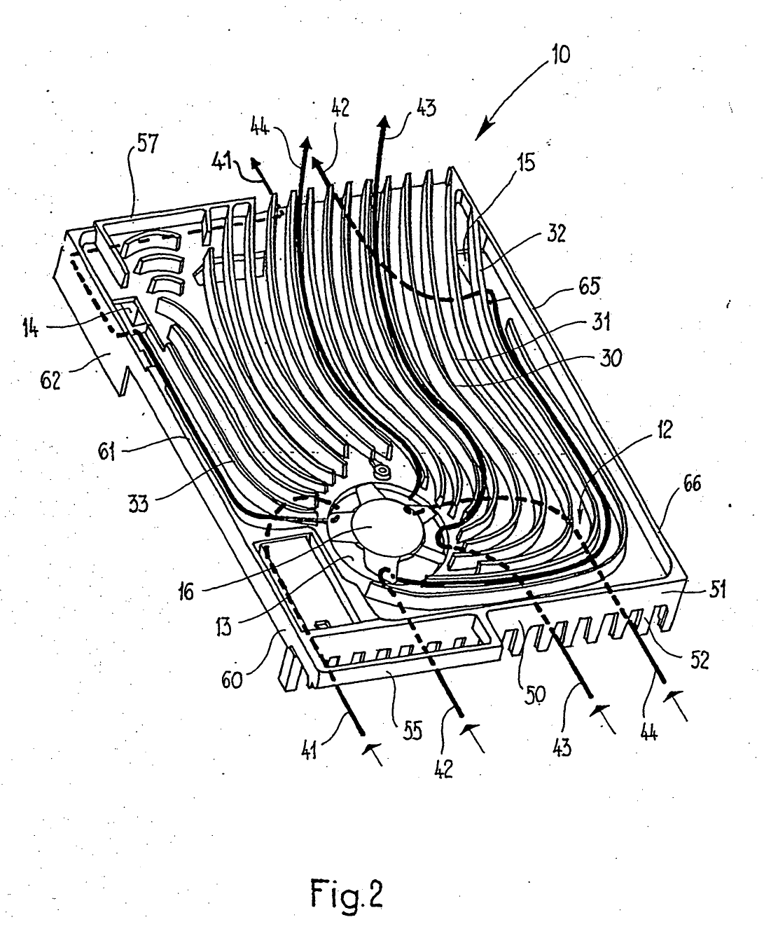

The electronics arrangement which is illustrated in FIGS. 1 and 2 comprises a flat mount structure 10, which is formed essentially from a printed circuit board 11, which is equipped on merely one side with electronic components 20, 21, 22, 23, and from a cold plate 12 (also referred to as a heat sink 12) which is provided with cooling ribs 30, 31, 32, 33 on one side. The printed circuit board 11 and the cold plate 12 are both in the form of flat, rectangular panels, with essentially identical rectangular shapes, with the cold plate 12 being connected by the main face on which there are no cooling ribs to the main face of the printed circuit board 11 on which there are no electronic components such that at least some of the heat losses which are produced by the electronic components 20, 21, 22, 23 that are arranged on the printed circuit board 11 are dissipated by means of thermal conduction to the cooling ribs 30, 31, 32, 33 of the cold plate 12. The vast majority of the cooling ribs 30, 31, 32, 33 are at the same time in the form of guidance walls 30, 31, 32, 33 for guiding the cooling air flow 41, 42, 43, 44, which will be described in the following text.

Overall, the mount structure 10 which is illustrated in FIGS. 1 and 2 is in the form of an essentially flat rectangular panel (also referred to in the following text as a mounting board 10) with two rectangular main faces 11, 12, with one main face 11 (also referred to in the following text as the printed circuit board face 11) being equipped with electronic components 20, 21, 22, 23, and with the other main face 12 (also referred to in the following text as the heat sink face 12) being provided with cooling ribs 30, 31, 32, 33. FIG. 1 shows a perspective view of the printed circuit board face 11 of the mount structure 10, while FIG. 2 shows a perspective view of the heat sink face 12 of the mount structure 10.

The electronics arrangement which is illustrated in the figures, and its mounting board 10 are formed with covering panels (which are not illustrated), which will be described in the following text, as a push-in unit which can be pushed as an entity into a rack (not illustrated) which is designed to hold further similar push-in units. That end face of the mounting board 10 which is arranged at the front of the rack after being pushed into the rack is referred to in the following text as the front face of the mounting board 10, and that end face which is essentially parallel to the front face and which forms the edge of the mount plate 10 furthest away from the front face is referred to as the rear face of the mounting board 10.

At its front edge, the mounting board 10 is fit with an essentially rectangular front wall 50, at right angles to the plane of the panel of the mounting board 10. This front wall 50 thus projects beyond the panel surfaces of the two main surfaces of the mounting board 10 both on the printed circuit board and on the heat sink side, with that part 52 of the front wall 50 which projects on the printed circuit board side being provided with a large number of passages, while the part 51 which projects on the heat sink side is essentially in the form of a homogeneous, continuous wall. The passages or openings in the front wall part 52 which projects on the printed circuit board side are used as air inlet openings for the cooling air flow 41, 42, 43, 44 which will be described in the following text.

In each case one side wall 60, 65, which extends from the front to the rear of the mounting board 10, is arranged at right angles to the mounting board 10 along the two longitudinal faces of the mounting board 10. On the heat sink side, these two side walls 60, 65 project over their entire length beyond the board surface of that main surface 12 of the mounting board 10 which is on the heat sink side, and are in the form of continuous wall parts 61, 66 there, while, on the printed circuit board side, they project beyond the board surface of that main surface 11 of the mounting board 10 which is on the printed circuit board side only in an area 62, 67 which is adjacent to the rear face, and are flush with this main surface, or do not project beyond it, elsewhere.

A rear wall is fit to the rear face of the mounting board 10, at right angles to it, projects beyond the board surface of that main surface 12 of the mounting board 10 which is on the heat sink side only on one half 57 of the length of the rear face, and projects beyond the board surface of that main surface 11 of the mounting board 10 which is on the printed circuit board side only on the other half 58. The rear wall part 58 which projects on the printed circuit board side is provided with passages which are used as air outlet openings for the component 41, 42 on the printed circuit board side of the cooling air flow 41, 42, 43, 44, which will be described in the following text. Once the mounting board 10 has been assembled together with the covering panels, which will be described in the following text to form a push-in unit, that half of the rear face which is left free on the printed circuit board side is blocked completely by a connecting plug, so that no cooling air can emerge there. On the printed circuit board side, the cooling air can emerge through the rear wall only in the region of the rear wall part 58 which is provided with passages.

The rear wall part 57 which projects on the heat sink side is designed to be continuous and the cooling air cannot pass through it. The component 43, 44 on the heat sink side of the cooling air flow 41, 42, 43, 44, which will be described in the following text, emerges through the rear face half which is left free on the heat sink side, and which is thus used as an air outlet opening on the heat sink side.

Overall, the mounting board 10 is provided on the heat sink side, along the front face, along the two longitudinal faces and on half of the rear face, with continuous edge walls 51, 57, 61, 66 which are arranged at right angles to the mounting board and project to a uniform height above the panel surface of that main surface 12 of the mounting board 10 which is on the heat sink side, where they prevent air flows parallel to the mounting board 10 flowing toward the mounting board 10, or flowing away from the mounting board 10. On the printed circuit board side, the mounting board 10 is provided with continuous edge walls 62, 67 only in the two areas of the longitudinal faces which are adjacent to the rear face, and these continuous edge walls 62, 67 prevent air flows which are parallel to the mounting board 10 flowing toward the mounting board 10 or flowing away from the mounting board 10. The other edge areas are either free of edge walls which project beyond the board surface of that main surface 11 of the mounting board 10 that is on the printed circuit board side, or they are provided with edge walls 52, 58 which have through-openings for the cooling air.

An essentially circular passage 13 is formed in the mounting board 10 approximately centrally in the front half of the mounting board 10, and passes essentially at right angles through the two main faces 11, 12 of the mounting board 10. A fan 16, which is provided with an impeller, is placed resting on the heat sink face 12 of the printed circuit board 10 such that its axial inlet opening is arranged such that it is flush with the cooling air passage 13. The axis of the impeller is thus arranged essentially at right angles to the main faces 11, 12 of the mounting board 10. The thickness of this fan 16 (measured in the direction of the axis of the impeller, which is also referred to as the fan axis) is of such a size that the fan 16 does not project beyond the edge walls 51, 57, 61, 66 and/or beyond the highest cooling ribs 30, 31, 32, 33 on the heat sink side. The fan 16 is operated in such a way that it sucks cooling air into the cooling air passage 13 on the printed circuit board side, and blows it out radially along the cooling ribs 30, 31, 32, 33 on the heat sink side.

A further cooling air passage 14, 15 is in each case formed in the vicinity of the two side edges in the rear half of the mounting board 10, with these two further cooling air passages 14, 15 once again passing through both main faces 11, 12 of the mounting board 10 essentially at right angles. The two further cooling air passages 14, 15 are arranged immediately adjacent to the longitudinal side edge regions of the mounting board 10 in which, on the printed circuit board side, the side walls 62, 67 project beyond the board surface of the main surface 11 of the mounting board 10.

The mounting board 10 which is illustrated in FIGS. 1 and 2 is also provided on the printed circuit board side and on the heat sink side with covering panels (not shown) which are parallel to the mounting board 10 and prevent air flows at right angles to the plane of the board toward the mounting board 10 and away from the mounting board 10. The mounting board 10 is assembled with these covering panels to form a push-in unit which can be pushed into a rack (not shown) as an entity. The covering panels are provided with additional flow guidance means such as walls, ribs and the like, in order to optimize the cooling air flow in terms of reducing noise levels and/or the cooling efficiency. Furthermore, the covering panel on the printed circuit board side is provided with a separating wall which bounds the areas around the first cooling air passage 13 from the areas around the further cooling air passages 14, 15, in order to prevent the cooling air on the printed circuit board side from flowing back in the further cooling air passages 14, 15 to the first cooling air passage 13.

In another embodiment of the invention, which is not shown in the figures, one or both of the covering panels which have been mentioned is or are omitted. The mounting board according to this embodiment of the invention is arranged immediately adjacent to further mounting boards and/or a rack or housing walls both on the printed circuit board side and on the heat sink side after being pushed into a rack, with these mounting boards and/or rack or housing walls having a similar board shape to that of the mounting board and being arranged parallel to it, thus resulting essentially only in air flows which are parallel to the planes of the boards.

A handle 55 is also fit to the front wall 50 in order to push the mounting board 10 into the housing and pull it out of the housing, projecting forward from the front wall 50 essentially as an extension of the plane of the mounting board.

In order to produce a cooling air flow 41, 42, 43, 44, the fan 16 which is inserted into the cooling air passage 13 is operated in such a way that it sucks the cooling air into the cooling air passage 13 on the printed circuit board side, and blows it out radially on the heat sink side along the cooling ribs 30, 31, 32, 33. This results in a cooling air flow 41, 42, 43, 44 being produced in such a way that the cooling air is first of all sucked in through the air inlet openings which are formed in the front wall 50 on the printed circuit board side. The cooling air flow 41, 42, 43, 44 is shown by the arrows 41, 42, 43, 44 in the figures. After flowing through the air inlet openings, the cooling air flows essentially parallel to the mounting board 10, along its main surface 11 on the printed circuit board side, to the cooling air passage 13 that is provided with the fan 16, and in the process cools the electronic components 20, 21 of the electronics arrangement which are located on the flow paths 41, 42, 43, 44 between the air inlet openings and the cooling air passage 13.

Forced by the fan 16, all of the cooling air 41, 42, 43, 44 then flows through the cooling air passage 13 that is provided with the fan 16, and is thus passed to the heat sink side 12 of the mounting board 10.

There, a portion 43, 44 of the cooling air flow 41, 42, 43, 44 is passed from the cooling air passage 13, which is provided with the fan 16, to the rear face of the mounting board 10 by means of a number of cooling ribs 30, 31 which are in the form of cooling air guidance walls 30, 31, with heat being dissipated by means of convection to the cooling air from the guidance walls 30, 31 which guide this portion 43, 44 of the cooling air flow 41, 42, 43, 44. This portion of the cooling air flow 43, 44 is then blown out through that half of the mounting board rear face which is used as the air outlet opening on the heat sink side, and where there is no rear wall on the heat sink side.

Another portion 41, 42 of the cooling air flow 41, 42, 43, 44 is passed from the cooling air passage 13, which is provided with the fan 16, to the two further cooling air passages 14, 15 in the rear-face side regions of the mounting board 10 by means of further cooling ribs 32, 33 which are at the same time in the form of cooling air guidance walls 32, 33, in the process convectively cooling the guidance walls 32, 33, which guide this portion 41, 42 of the cooling air flow 41, 42, 43, 44. This portion 41, 42 of the cooling air flow 41, 42, 43, 44 then flows through the two further cooling air passages 14, 15 back to the printed circuit board side 11 of the mounting board 10, where it flows past further electronic components 22, 23 to the rear face of the mounting board 10 on the printed circuit board side. In the process, the electronic components 22, 23 which are arranged on the flow path between the further passages 14, 15 and the rear face of the mounting board 10 are likewise convectively cooled. After this, this portion 41, 42 of the cooling air flow 41, 42, 43, 44 is blown out via the rear face of the mounting board 10 through the passages, which are used as air outlet openings on the printed circuit board side, in the rear wall part 58 which projects on the printed circuit board side.

In summary, it can be stated that the invention provides an electronics arrangement having a cooling apparatus which is space-saving and allows efficient cooling of electronic components in the electronics arrangement.

1. An electronics arrangement having at least one fan and at least one essentially flat mount structure which is equipped with one or more electronic components and is provided with one or more cooling ribs, comprising a cooling air passage which is formed in the mount structure, with the fan and the cooling air passage being designed and arranged such that the fan produces a cooling air flow such that the cooling air flows along one face of the mount structure in a cooling function whereby at least one electronic component and/or a cooling rib are cooled, then flows through said cooling air passage, after which it flows along the other face of the mount structure in a function whereby at least one electronic component and/or a cooling rib are cooled.

2. The electronics arrangement as claimed in claim 1, characterized in that the fan is fit to the mount structure or to a holding apparatus which is connected to the mount structure.

3. The electronics arrangement as claimed in claim 2, characterized in that the fan is of such a size and is arranged on the mount structure such that it does not project above the highest components and/or cooling ribs in the direction at right angles to the surfaces of the main faces of the flat mount structure.

4. The electronics arrangement as claimed in claim 2, characterized in that the fan is arranged radially in the cooling air passage or in its immediate vicinity.

5. The electronics arrangement as claimed in claim 3, characterized in that the fan is provided at one or at both axial longitudinal ends with in each case one cover which is arranged transversely with respect to the fan axis, and which covers prevent air from being sucked in or blown out in the axial direction.

6. The electronics arrangement as claimed in claim 1, characterized in that the mount structure comprises a printed circuit board, which is equipped with electronic components on merely one side, and a cold plate which is provided with cooling ribs on merely one side, with the cold plate being connected by its face on which there are no cooling ribs to the face of the printed circuit board, on which there are no electronic components.

7. The electronics arrangement as claimed in claim 1, characterized by the electronic components, the cooling ribs and the fan being arranged such that the cooling air flow which is produced by the fan initially cools at least one electronic component on one face of the mount structure, then flows through the cooling air passage, after which it cools at least one cooling rib on the other face of the mount structure.

8. The electronics arrangement as claimed in claim 1, characterized in that at least some of the cooling ribs are designed and arranged in the form of flow guidance walls which, on at least one face of the mount structure, define channel walls for the cooling air flow.

9. The electronics arrangement as claimed in claim 8, characterized in that a covering panel which is essentially parallel to the flat mount structure, or a covering element, is arranged on that face which faces away from the mount structure of the cooling ribs which define the cooling air channels, such that at least one of the cooling air channels is bounded on two sides by cooling ribs, on a third side by the mount structure, and on a fourth side, which is opposite this third side, by the covering panel or the covering element.

10. The electronics arrangement as claimed in claim 1, characterized in that at least one further cooling air passage is formed in the mount structure, and flow guidance means are arranged such that, after flowing along the first face of the mount structure and flowing through the first cooling passage which leads from the first face to the second face of the mount structure, at least some of the cooling air is passed to the further cooling air passage with the aid of the flow guidance means on the second face of the mount structure, and flows through this cooling air passage back to the first face of the mount structure in order then once again to flow along the first face of the mount structure in a function whereby at least one electronic component and/or a cooling rib are cooled.

11. The electronics arrangement as claimed in claim 1, characterized by the fan, the cooling air passage or passages and, if appropriate, the flow guidance means being arranged such that the cooling air is sucked in through an air inlet which is arranged in the vicinity of a first end face of the mount structure, and in that the cooling air is blown out through an air outlet which is arranged in the vicinity of an end face of the mount structure other than this first end face.
